(19) United States
(12) Patent Application Publication
(10) Pub. No.: US 2015/0079505 A1
(43) Pub. Date: Mar. 19, 2015

(54) ALKALINE-DEVELOPABLE PHOTOSENSITIVE RESIN COMPOSITION, DRY FILM, CURED ARTICLE, AND PRINTED WIRING BOARD

(71) Applicant: Kenji Kato, Suzhou City (CN)

(72) Inventor: Kenji Kato, Suzhou City (CN)

(73) Assignee: TAIYO INK(SUZHOU) CO., LTD., Suzhou City (CN)

(21) Appl. No.: 14/394,179

(22) PCT Filed: Aug. 15, 2012
(86) PCT No.: PCT/JP12/70726

§ 371 Date: Oct. 13, 2014

(30) Foreign Application Priority Data
Jun. 29, 2012 (CN) 201210221950.8

(51) Int. Cl. G03F 7/038

(52) U.S. Cl. CPC G03F 7/0385
USPC 430/18; 430/280.1

(57) ABSTRACT

Provided is an alkaline developable photosensitive resin composition which does not contain crude particles, has excellent storage stability, can avoid the deterioration of working environments, and contains few substances toxic to human bodies. The alkaline developable photosensitive resin composition is characterized by comprising (A) a resin containing a carboxyl group, (B) a photopolymerization initiator, (C) a compound having at least two ethylenically unsaturated groups per molecule, and (D) a dibasic acid ester.

### FIELD OF TECHNOLOGY

The present invention concerns an alkali developing type photosensitive resin composition, dry film, cured product, and printed circuit board suitable for the formation of printed circuit board solder resists, etc.; in particular, it concerns an alkali developing type photosensitive resin composition that can form a pattern of an alkali developing type photosensitive resin composition cured paint film having little harmful substance for the human body, a dry film that is obtained by coating such an alkali developing type photosensitive resin composition onto a carrier film and drying it, a cured product of such an alkali developing type photosensitive resin composition or such a dry film, and a printed circuit board that has such a cured product.

### BACKGROUND TECHNOLOGY

At present, for high precision and high density, the image formation on some consumer printed circuit boards and on almost all industrial printed circuit boards is made by ultraviolet radiation followed by developing, and a liquid developing type solder resist ink is used that undergoes finishing curing (main curing) by heat or light irradiation. And out of concern for environmental problems, what is mainly used is a liquid solder resist ink of alkali developing type that uses a dilute alkaline aqueous solution as the developing solution. As the alkali developing type solder resist ink that uses such a dilute alkaline aqueous solution, for example there is widespread use of liquid solder resist inks, such as those listed in patent reference 1, from an activated energy ray setting resin in which polybasic anhydride is added to the reaction product of a novolac-type epoxy compound and an unsaturated monocarboxylic acid, photopolymerization initiators, organic solvents, filler powder, and epoxy compounds.

Among these, for the role of photopolymerization initiators on solder resists, we can cite them as the starting point for thermosetting reactions during optical exposure. Specifically, upon exposure to light, a photopolymerization initiator absorbs the light, activates, and breaks down, and an activated photopolymerization initiator reacts with monomer, oligomer, and other photosensitive resins. The reacted photosensitive resin component increases its molecular weight and solidifies (hardens, is cured) by chain-reaction three-dimensional crosslinking reactions. In this way, a photopolymerization initiator plays an important role in forming a solder resist.

On the other hand, what is required for solder resist ink, in which many components are mixed as above and which is generally dispersed and formed on three rolls, is compatibility with the components and solubility in the organic solvent. The inorganic components can be dispersed by roll dispersion, but the organic components are not easily dispersed by roll dispersion. Thus it is essential that the organic components be dissolved and dispersed by the organic solvent. If the dissolution of the organic components is insufficient, then without complete dissolution they may remain in the composition in the form of coarse grains. In particular, if the aforesaid photopolymerization initiator that is contained on the solder resist ink does not fully dissolve and remains in the composition in the form of coarse grains, then the optical curing reactions will be insufficient, and the optical curing reactions that should happen cannot be hoped for. As a specific inadequacy, we can cite the reduction in the paint film properties, such as a reduction in the solder heat resistance. In addition, if undissolved photopolymerization initiator remains within the solder resist composition product, then the undissolved photopolymerization initiator will appear as granules on the dried paint film surface after printing and drying, which will detract from how the surface looks. Therefore what has been wanted is an organic component, in particular, an organic solvent that has high solubility and compatibility with the photopolymerization initiator.

As organic solvents, oil-based aromatic solvents, glycol ethers, and glycol esters are generally cited, and among these what have been used are organic solvents that have the appropriate volatilization rate, in consideration of storage stability, workability, and solubility with respect to the organic raw materials. However, oil-based aromatic solvents, although they have excellent solubility with respect to organic raw materials, contain naphthalene, which is suspected of being a carcinogen, and ways to deal with this have been wanted out of concern for adverse effects on the human body.

From the foregoing, what has been wanted is liquid solder resist ink that has no coarse grains, has excellent storage stability, suppresses worsening of the working environment, and has little substance that is harmful to the human body.

### PRIOR ART REFERENCES

### Patent References

Patent reference 1: Unexamined patent S61-243869 [1986]

### OVERVIEW OF THE PATENT

### Problems that the Invention is to Solve

In view of the above problems, the purpose of the present invention is to provide an alkali developing type photosensitive resin composition that makes it possible to form a pattern of cured paint film that has no coarse grains, has excellent storage stability, suppresses worsening of the working environment, and has little substance that is harmful to the human body; a dry film that is obtained by coating a carrier film with such a photosensitive resin composition and drying it; a cured product of such photosensitive composition or such dry film, and a printed circuit board that has such a cured product.

### Means for Solving the Problems

As a result of repeated diligent research to solve the above problems, the inventors of the present invention have arrived at the present invention having discovered that in alkali developing type photosensitive resin compositions, the above problems can be solved by using, as an organic solvent for the dissolution and dilution of synthetic resins, specified organic solvents that have excellent solubility and have little substance that is harmful to the human body.

That is, the present invention provides

[1] An alkali developing type photosensitive resin composition that is characterized in that it contains a carboxyl group-containing resin (A), a photopolymerization initiator (B), a compound (C) that has two or more ethylenic unsaturated groups in its molecule, and a dibasic acid ester (D).

[2] An alkali developing type photosensitive resin composition as described in [1] in which the dibasic acid ester (D) is a mixture of (a) 0 to 40 wt % dialkyl adipate, (b) 40 to 80 wt % dialkyl glutarate, and (c) 5 to 40 wt % dialkyl succinate.

Here, the alkyls of (a), (b), (c), which are each independent, are an alkyl group with 1 to 6 carbon atoms or cycloalkyl group with 5 to 8 carbon atoms.

[3] An alkali developing type photosensitive resin composition as described in [1] or [2] in which the dibasic acid ester (D) is a mixture of dimethyl adipate, dimethyl glutarate, and dimethyl succinate.

[4] An alkali developing type photosensitive resin composition as described in any of items [1] to [3] in which the content of the dibasic acid ester (D) is 1 to 60 parts by weight per 100 parts by weight of the carboxyl group-containing resin (A).

[5] An alkali developing type photosensitive resin composition as described in any of items [1] to [4] that is characterized in that it also contains a thermosetting component (E).

[6] An alkali developing type photosensitive resin composition as described in any of items [1] to [5] that is used coated onto the substrate.

[7] A dry film that is obtained by coating onto a carrier film, and drying, an alkali developing type photosensitive resin composition as described in any of items [1] to [5].

[8] A cured product that is characterized in that it is obtained by taking an alkali developing type photosensitive resin composition as described in any of items [1] to [5], or a dry film that is obtained by coating a carrier film with such an alkali developing type photosensitive resin composition and drying it, and performing photocuring, or photocuring and thermosetting, on the substrate.

[9] A printed circuit board that is characterized in that it has a cured product that it is obtained by taking an alkali developing type photosensitive resin composition as described in any of items [1] to [5], or a dry film that is obtained by coating a carrier film with such an alkali developing type photosensitive resin composition and drying it, and performing photocuring, or photocuring and thermosetting.

### Effects of the Invention

The alkali developing type photosensitive resin composition of the present invention, by using as an organic solvent a dibasic acid ester (D) which has excellent solubility, eliminates the coarse grains derived from the photopolymerization initiator or other organic components, improves the properties of the cured paint film, and reduces the appearance blemishes on the cured paint film.

And from the fact that the dibasic acid ester (D) of the present invention is particularly excellent in biodegradation, it can provide a printed circuit board that has an alkali developing type photosensitive resin composition with little content of harmful substances that adversely affect the human body, a dry film that is obtained by coating a carrier film with such a photosensitive resin composition and drying it, a cured product of such a photosensitive composition or of such a dry film, and such a cured product.

In addition, the alkali developing type photosensitive resin composition, by using as an organic solvent a dibasic acid ester (D) that has the appropriate volatilization rate, can suppress any rise in viscosity of the alkali developing type photosensitive resin composition, thereby making it possible to provide an alkali developing type photosensitive resin composition with excellent storage stability.

### EMBODIMENTS OF THE INVENTION

The alkali developing type photosensitive resin composition of the present invention contains a carboxyl group-containing resin (A), a photopolymerization initiator (B), a compound (C) that has two or more ethylenic unsaturated groups in its molecule, and a dibasic acid ester (D). In such case, by the fact that the solubility in an organic component such as the photopolymerization initiator is excellent, a composition is obtained in which a cured paint film without coarse grains can be formed, good storage stability can be obtained, and the content of harmful substances that will adversely affect the human body is reduced.

In the following we describe the constituent components in the alkali developing type photosensitive resin composition of the present invention. Because it is a feature of the alkali type photosensitive resin composition of the present invention that it contains a dibasic acid ester (D) as a mandatory component, first we discuss the dibasic acid ester (D).

It is particularly preferred that the proportion of each components that makes up the dibasic acid ester (D) that is contained in the alkali developing type photosensitive resin composition of the present invention be 0 to 40 wt % dialkyl adipate, (b) 40 to 80 wt % dialkyl glutarate, and (c) 5 to 40 wt % dialkyl succinate. Any departure from these quantities might affect the volatilization rate, and the following problems are listed as drawback for the alkali developing type photosensitive resin composition of the present invention.

That is, if the above upper limits are exceeded, the volatilization rate will slow down and a large quantity of dibasic acid ester (D) will remain in the alkali developing type photosensitive resin composition, and what should be dry to the touch will be sticky.

On the other hand, if less than the above lower limits, the volatilization rate will speed up, the viscosity of the alkali developing type photosensitive resin composition will increase, and the storage stability will become worse.

The alkyls of components (a) to (c) are each independent, and are an alkyl group with 1 to 6 carbon atoms or cycloalkyl group with 5 to 8 carbon atoms, but an alkyl group of 4 or fewer carbon atoms is preferable, and a methyl group is more preferable.

The alkyls of components (a) to (c) may be the same in each component, or may be esters of different alkyls.

With alkyl groups of 5 or more carbon atoms, the volatility will be somewhat meager, and after drying the dry-to-the-touch condition will be poor.

In this embodiment, as alkyl groups with 1 to 6 carbon atoms, we can list, for example, methyl, ethyl, propyl, isopropyl, butyl, sec-butyl, t-butyl, pentyl, hexyl, and other alkyl groups. As cycloalkyl groups of 5 to 8 carbon atoms, we can list, for example, cyclopentyl, cyclohexyl, cycloheptyl, cyclooctyl, dimethyl cyclohexyl, and other cycloalkyl groups.

For the blending proportions of the above dibasic acid esters (D) 1 to 60 parts by weight per 100 parts by weight of the below-described carboxyl group-containing resin (A) is appropriate, and preferable is 5 to 40 parts by weight. If the quantity of dibasic acid ester (D) used is less than the above range, the solubility with respect to the organic components will be poor, and on the other hand if this quantity is too great, the volatility will be somewhat meager, and the dry-to-the-touch feeling after drying will be poor, which is not desirable.

The ratio of (a) dialkyl adipate as a proportion of the dibasic acid ester (D) is 0 to 40 wt %, and more preferably 5 to 30 wt %. Either one species or a mixture of two or more species of (a) dialkyl adipate may be used. The ratio of (b) dialkyl glutarate as a proportion of the dibasic acid ester (D) is 40 to 80 wt %, and more preferably 50 to 70 wt %. Either one species or a mixture of two or more species of (b) dialkyl glutarate may be used.

The ratio of (c) dialkyl succinate as a proportion of the dibasic acid ester (D) is 5 to 40 wt %, and more preferably 10 to 30 wt %. Either one species or a mixture of two or more species of (c) dialkyl succinate may be used.

And because the dissolving power of the dibasic acid ester (D) of the present invention is high with respect to the components included in the alkali developing type photosensitive resin composition, especially with respect to the photopolymerization initiator, it is possible to prevent the occurrence of what is known as reagglomeration, in which crystalline impurities are deposited in the composition, when stored at a low temperature (5° C. or less), giving good storage stability to the alkali developing type photosensitive resin composition.

And in order to further adjust the solubility and volatilization rate, etc., one may suitably add to the organic solvent that is contained in the alkali developing type photosensitive resin composition of the present invention, in addition to the dibasic acid ester (D), solvents that have a (di)propylene glycol skeleton, solvents such as propionate esters, or glycol ether and glycol ester solvents, which are safe for the global environment. As solvents having a (di)propylene glycol skeleton, we can list, for example, propylene glycol monomethyl ether acetate, propylene glycol monoethyl ether acetate, dipropylene glycol monomethyl ether, dipropylene glycol monomethyl ether acetate, dipropylene glycol monoethyl ether acetate, etc. And as propionate esters, we can list, for example, methyl propionate, ethyl propionate, propyl propionate, methyl methoxy propionate, ethyl methoxy propionate, etc. And as solvents that have a glycol ether or glycol ester skeleton, we can list, for example diethylene glycol monomethyl ether, diethylene glycol monoethyl ether acetate, etc.

Also, in the present invention, dibasic acid ester (D) or an organic solvent other than the dibasic acid ester (D) can be used when the carboxyl group-containing resin (A) is manufactured, and can also be contained in the alkali developing type photosensitive resin composition of the present invention as is, without isolating it, after the reactions have ended.

Carboxyl Group-Containing Resin (A)

Compounds such as those listed in the following (including oligomers or polymers) are preferable as specific examples of the carboxyl group-containing resin (A) that can suitably be used in the alkali developing type photosensitive resin composition of the present invention.

We can cite
(1) a carboxyl group-containing photosensitive resin obtained by copolymerizing an unsaturated carboxylic acid, such as (meth)acrylic acid, and one or more species of a compound having an unsaturated double bond other than that,
(2) a carboxyl group-containing photosensitive resin obtained by adding an ethylenic unsaturated group as a pendant to a copolymer of an unsaturated carboxylic acid such as (meth)acrylic acid and one or more species of a compound having an unsaturated double bond other than that, by a compound that has an unsaturated double bond with an epoxy group such as glycidyl (meth)acrylate or 3,4-epoxy cyclohexyl methyl (meth)acrylate, or chloride (meth)acrylate,
(3) a carboxyl group-containing photosensitive resin obtained by reacting an unsaturated carboxylic acid such as (meth)acrylic acid with a copolymer of a compound having an unsaturated double bond with an epoxy group such as glycidyl (meth)acrylate or 3,4-epoxy cyclohexyl methyl (meth)acrylate and a compound having an unsaturated double bond other than that, and reacting a polybasic acid anhydride with the resulting secondary hydroxyl group,
(4) a carboxyl group-containing photosensitive resin obtained by reacting a compound that has an unsaturated double bond with a hydroxyl group, such as 2-hydroxy ethyl (meth)acrylate, with a copolymer of an acid anhydride that has an unsaturated double bond, such as maleic acid anhydride, and a compound that has an unsaturated double bond other than that,
(5) a carboxyl group-containing photosensitive resin obtained by reacting an unsaturated monocarboxylic acid with a polyfunctional epoxy compound, and reacting a saturated or unsaturated polybasic acid anhydride with the resulting hydroxyl group,
(6) a photosensitive resin that contains a hydroxyl group and a carboxyl group that is obtained by reacting a saturated or unsaturated polybasic acid anhydride with a hydroxyl group-containing polymer such as a polyvinyl alcohol derivative, then reacting a compound that contains an unsaturated double bond with an epoxy group in its molecule, with the resulting carboxylic acid,
(7) a carboxyl group-containing photosensitive resin that is obtained by reacting a saturated or unsaturated polybasic acid anhydride with the reaction product of a polyfunctional epoxy compound, an unsaturated monocarboxylic acid, at least one alcoholic hydroxyl group in its molecule, and a compound having one reactive group other than an alcoholic hydroxyl group that reacts with an epoxy group,
(8) a carboxyl group-containing photosensitive resin that is obtained by reacting an unsaturated monocarboxylic acid with a polyfunctional oxetane compound that has at least two oxetane rings in its molecule, and reacting a saturated or unsaturated polybasic acid anhydride with a primary hydroxyl group in the resulting modified oxetane resin, and,
(9) a carboxyl group-containing photosensitive resin that is obtained by reacting an unsaturated monocarboxylic acid with a polyfunctional epoxy compound, then a polybasic acid anhydride, then further reacting with the resulting carboxyl group-containing organic resin a compound that has in its molecule one ox[y]silane ring and one or more ethylenic unsaturated group,
(10) a carboxyl group-containing photosensitive resin that is obtained by reacting an unsaturated monocarboxylic acid with a bifunctional epoxy compound, and reacting a saturated or unsaturated polybasic acid anhydride with the hydroxyl group that is produced,
but there is no limitation to these items.

Preferred among these examples are the carboxyl group-containing resins of (2), (5), (7), and (9) above.

Also, in this specification, “(meth)acrylate” is a generic term for acrylate, methacrylate, and mixtures of these; the same applies to other similar expressions as well.

Because the above carboxyl group-containing resin (A) has many free carboxyl groups on side chains of the backbone polymer, it can be developed with a dilute alkaline aqueous solution.

And the acid value of the above carboxyl group-containing resin (A) is preferably in the range 40 to 200 mgKOH/g, and more preferably in range 45 to 120 mgKOH/g. If the acid value of the carboxyl group-containing resin is less than 40 mgKOH/g, alkali developing will be difficult, and on the other hand if it exceeds 200 mgKOH/g, dissolving of the light-exposed parts by the developing solution will proceed, making the lines narrower than necessary, and in some cases leading to dissolving and peeling with the developing solution with no distinction between the exposed parts and the unexposed parts, creating the undesirable outcome of making it difficult to draw normal resist patterns.

Also, the weight average molecular weight of the above carboxyl group-containing resin (A) differs depending on the resin skeleton, but generally it is preferred that it be in the range 2,000 to 150,000, and more particularly in the range 5,000 to 100,000. If the weight average molecular weight is less than 2,000, the tack-free performance after the substrate is coated and dried might be inferior, and sometimes the moisture resistance of the paint film after exposure to light will be poor, film thinning will occur during developing, and the image resolution will be large and inferior. On the other hand if the weight average molecular weight exceeds 150,000, the developability might be significantly worse, and the storage stability might be inferior.

Photopolymerization Initiator (B)

As photopolymerization initiators (B) that can suitably be used in the alkali developing type photosensitive resin composition of the present invention, we can list

benzoin and benzoin alkyl ethers such as benzoin, benzoin methyl ether, benzoin ethyl ether, and benzoin isopropyl ether;
acetophenones such as acetophenone, 2,2-dimethoxy-2-phenyl acetophenone, 2,2-diethoxy-2-phenyl acetophenone, 1,1-dichloro acetophenone, and 1-[4-(4-benzoyl phenyl sulfanyl)-2-methyl-2-(4-methyl phenyl sulfanyl)propane-1-one;
aminoacetophenones such as 2-methyl-1-[4-(methylone)phenyl]-2-morpholino propanone-1, and 2-benzyl-2-dimethyl amino-1-(4-morpholino phenyl)-butanone;
anthraquinones such as 2-methyl anthraquinone, 2-ethyl anthraquinone, 2-tertiary-butyl anthraquinone, and 1-chloro anthraquinone;
thioxanthones such as 2,4-dimethyl thioxanthone, 2,4-diethyl thioxanthone, 2-chloro thioxanthone, and 2,4-diisopropyl thioxanthone;
ketals such as acetophenone dimethyl ketal and benzyl dimethyl ketal;
benzophenones or xanthones such as benzophenone;
acyl phosphine oxides such as bis(2,6-dimethoxy benzoyl)(2,4,4-trimethyl pentyl)phosphine oxide, bis(2,4,6-trimethyl benzoyl)-phenyl phosphine oxide, 2,4,6-trimethyl benzoyl diphenyl phosphine oxide, and ethyl-2,4,6-trimethyl benzoyl phenyl phosphinate;
and various types of peroxides, etc.; these well known and commonly used photopolymerization initiators may be used either singly or in combinations of two or more species.

As a preferable mode of the photopolymerization initiator (B), we can cite 2-methyl-1-[4-(methylone)phenyl]-2-morpholino propanone-1, and as commercial products, Irgacure 907 and 2-benzyl-2-dimethyl amino-1-(4-morpholino phenyl)-butanone-1, made by BASF Japan, and as a commercial product, Irgacure 369 made by BASF Japan, etc.

For the blending ratio of these photopolymerization initiators (B), 0.01 to 30 parts by weight per 100 parts by weight of the aforesaid carboxyl group-containing resin (A) is suitable, and 5 to 25 parts by weight is preferred. If the quantity of photopolymerization initiator used is less than the above range, the photocurability of the composition will be poor, and if on the other hand the quantity is too great, then for the properties as a solder resist, for example so-called halation, called line thickening, will readily occur, resulting in an undesirable reduction in chemical resistance and solder heat resistance, etc.

Compound (C) that has Two or More Ethylenic Unsaturated Groups in its Molecule

The compound (C) that has two or more ethylenic unsaturated groups in its molecule that is used in the alkali developing photosensitive resin composition of the present invention is cured by actinic energy rays and helps to make the carboxyl group-containing resin (A) insoluble or soluble in an alkaline aqueous solution. As specific examples of such a compound, we can list hydroxy alkyl acrylates such as 2-hydroxy propyl acrylate; mono- or diacrylates such as ethylene glycol, methoxy tetraethylene glycol, polyethylene glycol, and propylene glycol; acryl amides such as N,N-dimethyl acryl amide, N-methylol acryl amide, and N,N-dimethyl aminopropyl acryl amide; aminoalkyl acrylates such as N,N-dimethyl aminoethyl acrylate and N,N-dimethyl aminopropyl acrylate; polyvalent alcohols such as hexane diol, trimethylol propane, pentaerythritol, dipentaerythritol, and tris-hydroxy ethyl isocyanurate, or polyvalent acrylates such as ethylene oxide adducts or propylene oxide adducts of these; acrylates such as phenoxy acrylate, bisphenol A diacrylate, and ethylene oxide adducts or propylene oxide adducts of phenols of these; acrylates of glycidyl ethers such as glycerin diglycidyl ether, glycerin triglycidyl ether, trimethylol propane triglycidyl ether, and triglycidyl isocyanurate; and at least some one species of methacrylates corresponding to these acrylates.

In addition, we can list epoxy urethane acrylate compounds made by reacting a half-urethane compound of a hydroxy alkylate such as pentaerythritol acrylate or a diisocyanate such as isophorone diisocyanate, with a hydroxyl group of an epoxy acrylate resin made by reacting acrylic acid, or additionally an epoxy acrylate resin thereof, made by reacting acrylic acid with a polyfunctional epoxy resin such as cresol novolac type epoxy resin.

For the blending quantity of such a compound (C) that has two or more ethylenic unsaturated groups in its molecule, a ratio of 5 to 100 parts by weight per 100 parts by weight of the carboxyl group-containing resin (A) is preferred, and a ratio of 1 to 70 parts by weight is more preferable. If this blending quantity is less than 5 parts by weight per 100 parts by weight of the carboxyl group-containing resin (A), the photocurability of the resulting alkali developing type photosensitive resin composition will decline, and it will be difficult to form patterns by alkali developing following irradiation with actinic energy rays, which is undesirable. On the other hand if it is greater than 100 parts by weight, the solubility in the alkaline aqueous solution will decline, and the paint film will become brittle, which is undesirable.

Thermosetting Component (E)

In order to confer heat resistance to the alkali developing type photosensitive resin composition used in the present invention, it is preferable to blend in a thermosetting component (E) that has in its molecule two or more reaction groups (cyclical ether group and cyclical thioether group (hereafter abbreviated to at least one or the other of a cyclic (thio)ether group)).

The thermosetting component (E) is a compound that has in its molecule two or more groups, of one or two species, of a cyclic ether group or cyclic thioether group with a 3-, 4-, or 5-member ring; for example, we may list (E-1) a compound that has in its molecule at least two or more epoxy groups, that is, a polyfunctional epoxy compound, (E-2) a compound that has in its molecule at least two or more oxetanyl groups, that is, a polyfunctional oxetane compound, and (E-3) a compound that has in its molecule at least two cyclic thioether groups, that is, an episulfide resin, etc.

As the (E-1) polyfunctional epoxy compound, we can list, for example,

bisphenol A type epoxy resins such as (all brand names) jER 828, jER 834, jER 1001, and jER 1004 made by Mitsubishi Chemical Corp.; Epiclon 840, Epiclon 850, Epiclon 1050, and Epiclon 2055 made by DIC Co., YD-011, YD-013, YD-127, and YD-128 made by Tohto Kasei Co., D.E.R. 317, D.E.R. 331, D.E.R. 661, and D.E.R. 664 made by Dow Chemical Co.; Sumi-Epoxy ESA-011, ESA-014, ELA-115, and ELA-128 made by Sumitomo Chemical Co., and A.E.R. 330, A.E.R. 331, A.E.R. 661, and A.E.R. 664, made by Asahi Chemical Industry Co.;
bromated epoxy resins such as (all brand names) jER 152 and jER 165 made by DIC Co., Epotote YDB-400 and YDB-500 made by Tohto Kasei Co., D.E.R. 542 made by Dow Chemical Co., Sumi-Epoxy ESB-400 and ESB-700 made by Sumitomo Chemical Co., and A.E.R. 711 and A.E.R. 714 made by Asahi Chemical Industry Co.;
novolac type epoxy resins such as (all brand names) jER 152 and jER 154 made by Mitsubishi Chemical Corp., D.E.N. 431 and D.E.N 438 made by Dow Chemical Co., Epiclon N-730, Epiclon N-770, and Epiclon N-865 made by DIC Co., Epotote YDCN-701 and YDCN-704 made by Tohto Kasei Co., EPPN-201, EOCN-1025, EOCN-1020, EOCN-104S, and RE-306 made by Nippon Kayaku Co., Sumi-Epoxy ESCN-195X and ESCN-220 made by Sumitomo Chemical Co., and A.E.R. ECN-235 and ECN-299, made by Asahi Chemical Industry Co.;
bisphenol F type epoxy resins such as Epiclon 830 made by DIC Co., jER 807 made by Mitsubishi Chemical Corp., Epotote YDF-170, YDF-175, and YDF-2004 made by Tohto Kasei Co.;
hydrogenated bisphenol A type epoxy resins such as (brand names) Epotote ST-2004, ST-2007, ST-3000 made by Tohto Kasei Co.;
glycidyl amino type epoxy resins such as (all brand names) Epicoat 604 made by Mitsubishi Chemical Corp., Epotote YH-434 made by Tohto Kasei Co., and Sumi-Epoxy ELM-120 made by Sumitomo Chemical Co.;
hydantoin type epoxy resins;
alicyclic epoxy resins such as (all brand names) Celloxide 2021 made by Daicel Chemical Industries, Ltd.;
trihydroxy phenyl methane type epoxy resins such as (all brand names) YL-933 made by Mitsubishi Chemical Corp., T.E.N., EPPN-501, and EPPN-502 made by Dow Chemical Co.;
bixylenol type or biphenol type epoxy resins such as (all brand names) YL-6056, YX-4000, and YL-6121 made by Mitsubishi Chemical Corp., or mixtures thereof;
bisphenol S type epoxy resins such as (brand names) EBPS-200 made by Nippon Kayaku Co., EPX-30 made by ADEKA Co., and EXA-1514 made by DIC Co.;
bisphenol novolac type epoxy resins such as (brand name) jER 157S made by Mitsubishi Chemical Corp.;
tetraphenylol ethane type epoxy resins such as (all brand names) Epicoat YL-931 made by Mitsubishi Chemical Corp.;
heterocyclic epoxy resins such as (all brand names) TEPIC made by Nissan Chemical Industries, Ltd.;
diglycidyl phthalate resins such as Blemmer DGT made by Nippon Oil and Fats Co.;
tetraglycidyl xylenoyl ethane resins such as ZX-1063 made by Tohto Kasei Co.;
naphthalene group-containing epoxy resins such as ESN-190 and ESN-360 made by Nippon Steel Chemical Co., and HP-4032, EXA-4750, and EXA-4700 made by DIC Co.;
epoxy resins having a dicyclopentadiene skeleton such as HP-7200 and HP-7200H made by DIC Co.;
glycidyl methacrylate copolymer epoxy resins such as CP-50S and CP-50M made by Nippon Oil and Fats Co.;
in addition, cyclohexyl maleimide and glycidyl methacrylate copolymer epoxy resins;
epoxy-modified polybutadiene rubber derivatives (for example, PB-3600 made by Daicel Chemical Industries, Ltd., etc.) and CTBN-modified epoxy resins (for example, YR-102 and YR-450 made by Tohto Kasei Co., etc.), etc.,
but there is no limitation to these. These epoxy resins can be used either singly or in combinations of two species or more. Especially preferable among these are bisphenol A type epoxy resins and mixtures thereof.

As the (E-2) polyfunctional oxetane compounds, besides polyfunctional oxetanes such as bis[(3-methyl-3-oxetanyl methoxy)methyl]ether, bis[(3-ethyl-3-oxetanyl methoxy)methyl]ether, 1,4-bis[(3-methyl-3-oxetanyl methoxy)methyl]benzene, 1,4-bis[(3-ethyl-3-oxetanyl methoxy)methyl]benzene, (3-methyl-3-oxetanyl)methyl acrylate, (3-ethyl-3-oxetanyl)methyl acrylate, (3-methyl-3-oxetanyl)methyl methacrylate, (3-ethyl-3-oxetanyl)methyl methacrylate, and oligomers or copolymers, etc. thereof, we may list oxetane alcohol and novolac resins, poly(p-hydroxy styrene), curled-type bisphenols, calixarenes, calix resorcin arenes, or etherified products with a resin that has a hydroxyl group, such as silsesquioxane. Besides these, we can also list copolymers between an alkyl (meth)acrylate and an unsaturated monomer that has an oxetane ring.

As the (E-3) compound that has in its molecule at least two cyclic thioether groups, we can list, for example, the YL 7000 bisphenol A type episulfide resin made by Mitsubishi Chemical Corp., etc. And, using a similar synthesis method, one can also use an episulfide resin in which the oxygen atom of the epoxy group of the novolac type epoxy resin is substituted with a sulfur atom.

For the blended quantity of the above thermosetting component (E) that has two or more cyclic (thio)ether groups in its molecule, the cyclic (thio)ether group is preferably 0.6 to 2.0 equivalent weights per equivalent weight of each carboxyl group of the carboxyl group-containing resin, and more preferably in the range from 0.8 to 1.5 equivalent weights. If the blended quantity of the thermosetting component having two or more cyclic (thio)ether groups in the molecule of (E) is less than 0.6, then carboxyl groups will remain in the solder resist film, lowering the heat resistance, the alkali resistance, the electrical insulation, etc., which is undesirable. On the other hand, if it exceeds 2.0 equivalent weights, then by cyclic (thio)ether groups of low molecular weight remaining in the dried paint film, the strength and other properties of the paint film will decline, which is undesirable.

If one uses a thermosetting component that has two or more cyclic (thio)ether groups in the molecule of (E) above, then it is preferred that it contain a thermosetting catalyst. As such thermosetting catalysts, we can list, for example,

imidazole derivatives such as imidazole, 2-methyl imidazole, 2-ethyl imidazole, 2-ethyl-4-methyl imidazole, 2-phenyl imidazole, 4-phenyl imidazole, 1-cyano ethyl-2-phenyl imidazole, and 1-(2-cyano ethyl)-2-ethyl-4-methyl imidazole;
amine compounds such as dicyan diamide, benzyl dimethyl amine, 4-(dimethyl amino)-N,N-dimethyl benzyl amine, 4-methoxy-N,N-dimethyl benzyl amine, and 4-methyl-N,N-dimethyl benzyl amine, and hydrazine compounds such as dihydrazide adipate and dihydrazide sebacate;
phosphorus compounds such as triphenyl phosphine, and, as commercially available items, for example, 2MZ-A, 2MZ-OK, 2PHZ, 2P4BHZ, 2P4MHZ (all brand names of imidazole compounds) made by Shikoku Chemicals Corp., U-CAT35O3N and U-CAT35O2T (both brand names of block isocyanate compounds of methyl amine) made by San'apro Co., and DBU, DBN, U-CATSA102, and UCAT5002 (all a bicyclic amidine compound or a salt thereof), etc.

There is no limitation to these in particular; as long as it is an epoxy resin or oxetane compound thermosetting catalyst, or something that promotes the reaction of a carboxyl group with at least one of either an epoxy group or an oxetanyl group, it may be used either singly or as a mixture of two or more species. One may also use guanamine, acetoguanamine, benzoguanamine, melamine, 2,4-diamino-6-methacryloyl oxyethyl-S-triazine, 2-vinyl-2,4-diamino-S-triazine, 2-vinyl-4,6-diamino-S-triazine isocyanuric acid adducts, 2,4-diamino-6-methacryloyl oxyethyl-S-triazine isocyanuric acid adducts, etc. S-triazine derivative, and preferably, a compound that also functions as an agent to cause these to adhere to each other may be used together with the thermosetting catalyst.

Other Components

In addition, as necessary, the alkali developing type photosensitive resin composition of the present invention may be blended with

well known and commonly used inorganic or organic fillers such as barium sulfate, barium titanate, silicon oxide powder, spherical silica, talc, clay, magnesium carbonate, calcium carbonate, aluminum oxide, aluminum hydroxide, glass fiber, carbon fiber, and mica powder;
well known and commonly used colorants such as phthalocyanine blue, phthalocyanine green, iodine green, disazo yellow, crystal violet, titanium oxide, carbon black, and naphthalene black;
well known and commonly used thermal polymerization inhibitors such as hydroquinone, hydroquinone monomethyl ether, t-butyl catechol, pyrogallol, and phenone thiazine;
well known and commonly used thickeners such as fine-powder silica, organic bentonite, and montmorillonite;
and well known and commonly used additives such as silicone, fluorine, or macromolecular anti-foaming agents and at least one type of leveling agent; imidazole, thiazole, triazole, or other adhesion promotion agents or silane coupling agents; phenol, phosphorus, sulfur, or other antioxidants, and hindered amine light stabilizing agents, etc.

The dry film of the present invention is one in which a film (the carrier film) is coated with the alkali developing type photosensitive resin composition of the present invention and is dried; it has a carrier film and, formed on the carrier film, a layer that consists of the alkali developing type photosensitive resin composition of the present invention.

When making the dry film, the alkali developing type photosensitive resin composition of the present invention is diluted by the above organic solvent to a suitable viscosity, the top of the support body is coated to a uniform thickness with a comma coater, blade coater, rip coater, rod coater, squeeze coater, reverse coater, transfer roll coater, gravure coater, spray coater, etc., and normally it is dried for 1 to 30 minutes at a temperature of 50 to 130° C. to produce the film. There are no particular limits on the thickness of the coated film, but generally after drying the film thickness is 10 to 150 μm, and preferably it is appropriately selected in the range of 20 to 60 μm.

As the carrier film, a plastic film is used, and it is preferable to use a polyester film such as one of polyethylene terephthalate, polyimide film, polyamide imide film, polypropylene film, polystyrene film, etc. There are no particular limits on the thickness of the carrier film, but generally it is suitably selected in the range of 10 to 150 μm.

After a film is formed on the carrier film, it is preferable to laminate a peelable cover film onto the surface of the film for the purpose of preventing dust from sticking to the surface of the film. As the peelable cover film, one can use, for example, polyethylene film, polytetrafluoroethylene film, polypropylene film, or paper that has been given a surface treatment, and it would be good to ensure that the adhesion force between the film and the cover film is less than the adhesion force between the film and the support body when the cove film is peeled off.

If the alkali developing type photosensitive resin composition of the present invention is used for solder resist formation on a printed circuit board, then after adjusting it to the proper viscosity for the coating method as necessary, it is coated onto printed circuit board on which for example a circuit pattern is formed previously, by a method such as screen printing, curtain coating, spray coating, or roll coating, and as necessary a tack-free paint film can be formed by carrying out a drying treatment at a temperature of for example, about 60 to 100° C.

And in the case of the above dry film mode, it is attached onto the top of the base material using a hot roll laminator or the like (the photosensitive resin composition layer and the base material are brought into contact with each other so that they touch). In the case of a dry film that further has a peelable cover film on the photosensitive resin composition layer of the film, then after the cover film is peeled off, a hot laminator or the like is used to bring the photosensitive resin composition layer and the base material together so that they touch.

Then, exposure to light by active light rays cans done selectively through a photomask on which the prescribed light exposure pattern is formed, forming a resist pattern by developing, with the alkaline aqueous solution, the parts not exposed to light; in addition, by curing with, for example, UV radiation at 300 to 500 mJ/cm², and by causing thermosetting by heating to a temperature of about 140 to 180° C., in addition to the curing reactions of the above thermosetting component, polymerization of the photosensitive resin component is promoted, which makes it possible to improve the properties of the resulting resist film, including its heat resistance, solvent resistance, acid resistance, moisture absorption resistance, PCT resistance, adhesion, and electrical properties.

As the alkaline aqueous solution to be used in the above developing, one may use an alkaline aqueous solution of potassium hydroxide, sodium hydroxide, sodium carbonate, potassium carbonate, sodium phosphate, sodium silicate, ammonia, amine, etc. And suitable as the irradiation light source for causing photocuring are a low-voltage mercury lamp, a medium-voltage mercury lamp, a high-voltage mercury lamp, an ultra-high-voltage mercury lamp, a semiconductor laser, a solid-state laser, a xenon lamp, or a metal halide lamp, etc.

The photopolymerized resin composition of the present invention and the curable film formed by the dry film are suitable as a permanent film on a printed circuit board, including being suitable for solder resists and inter-layer insulating material.

The present invention is described in greater detail based on working examples and comparison examples, which do not, however, limit the technical scope or implementations of the present invention. Unless otherwise specified, “parts” and “%” in the working examples and comparison examples refer to parts and percent by weight. Tests of the state values of the composition of the following working example were carried out by the techniques described in the following.

### Synthesis Example 1

Into a four-opening flask with a stirrer and circulation cooler was put 214 parts Epiclon N-695, which is a cresol novolac type epoxy resin (made by DIC Co., epoxy equivalent weight=214), then were added 103 parts carbitol acetate and 103 parts dibasic acid ester solution (made by DuPont, brand name: DBE [dimethyl adipate: 10 to 25%, dimethyl glutarate: 55 to 65%, dimethyl succinate: 15 to 25%]), then heating and dissolving was done. Next, 0.1 parts hydroquinone was added as a polymerization inhibitor, and 2.0 parts triphenyl phosphine was added as a reaction catalyst. This mixture was heated to 95 to 105° C., 72 parts acrylic acid was gradually dripped in, and reactions were allowed to take place for 16 hours. The resulting reaction product was cooled to 80 to 90° C., 91.2 parts tetrahydrophthalic acid anhydride was added, reactions were allowed to take place for 8 hours, and after cooling, it was taken out. The carboxyl group-containing photopolymerization unsaturated compound that was obtained in this way, had a nonvolatile component of 65% and a solids acid value of 87.5 mgKOH/g. In the following, this reaction product solution is called varnish A.

### Synthesis Example 2

Into a four-opening flask with a stirrer and circulation cooler was put 214 parts Epiclon N-695, which is a cresol novolac type epoxy resin (made by DIC Co., epoxy equivalent weight=214), then were added 103 parts carbitol acetate and 103 parts oil-based aromatic solvent (made by Idemitsu Kosan, brand name: Ipzole 150), then heating and dissolving was done. Next, 0.1 parts hydroquinone was added as a polymerization inhibitor, and 2.0 parts triphenyl phosphine was added as a reaction catalyst. This mixture was heated to 95 to 105° C., 72 parts acrylic acid was gradually dripped in, and reactions were allowed to take place for 16 hours. The resulting reaction product was cooled to 80 to 90° C., 91.2 parts tetrahydrophthalic acid anhydride was added, reactions were allowed to take place for 8 hours, and after cooling, it was taken out. The carboxyl group-containing photopolymerization unsaturated compound that was obtained in this way had a nonvolatile component of 65% and a solids acid value of 87.5 mgKOH/g. In the following, this reaction product solution is called varnish B.

### Synthesis Example 3

Into a four-opening flask with a stirrer and circulation cooler was put 214 parts Epiclon N-695, which is a cresol novolac type epoxy resin (made by DIC Co., epoxy equivalent weight=214), then were added 103 parts carbitol acetate and 103 parts dipropylene glycol monomethyl ether (made by Toho Chemical Industry, brand name: Hisolve DPM), then heating and dissolving was done. Next, 0.1 parts hydroquinone was added as a polymerization inhibitor, and 2.0 parts triphenyl phosphine was added as a reaction catalyst. This mixture was heated to 95 to 105° C., 72 parts acrylic acid was gradually dripped in, and reactions were allowed to take place for 16 hours. The resulting reaction product was cooled to 80 to 90° C., 91.2 parts tetrahydrophthalic acid anhydride was added, reactions were allowed to take place for 8 hours, and after cooling, it was taken out. The carboxyl group-containing photopolymerization unsaturated compound that was obtained in this way had a nonvolatile component of 65% and a solids acid value of 87.5 mgKOH/g. In the following, this reaction product solution is called varnish C.

Using the carboxyl group-containing resin solutions of the above synthesis examples 1 to 3 (varnish A, varnish B, varnish C), blends were made with the various components and proportions (parts by weight) shown in Table 1, and after preliminary mixing with the stirrer, kneading was done in a three-roll mill, and alkali developing type solder resist ink was prepared.

TABLE 1
[Wex = Working example, Cex = Comparison example,
Ppi = photopolymerization initiator]

| | Wex | Wex | Wex | Wex | Wex | Cex | Cex |
|---|---|---|---|---|---|---|---|
| | 1 | 2 | 3 | 4 | 5 | 1 | 2 |
| varnish A | 150 | 150 | 150 | | 150 | | |
| varnish B | | | | | | 150 | |
| varnish C | | | | 150 | | | 150 |
| Ppi (B-1) | 10 | 10 | 10 | 10 | | 10 | 10 |
| Ppi (B-2) | | | | | 10 | | |
| DPHA (C-1) | 15 | 15 | 15 | 15 | 15 | 15 | 15 |
| dibasic acid ester | 10 | 7 | 5 | 15 | 7 | | |
| (D) | | | | | | | |
| Carbitol acetate | | | 5 | | | | 15 |
| DPM | | 5 | | | 5 | 5 | |
| oil-based aromatic | | | | | | 5 | |
| solvent | | | | | | | |
| thermosetting | 20 | 20 | 20 | 20 | 20 | 20 | 20 |
| component (E-1) | | | | | | | |
| thermosetting | 20 | 20 | 20 | 20 | 20 | 20 | 20 |
| component (E-2) | | | | | | | |
| filler | 120 | 120 | 120 | 120 | 120 | 120 | 120 |
| phthalocyanine | 1 | 1 | 1 | 1 | 1 | 1 | 1 |
| green | | | | | | | |
| dicyan diamide | 0.4 | 0.4 | 0.4 | 0.4 | 0.4 | 0.4 | 0.4 |
| fine-powder | 4 | 4 | 4 | 4 | 4 | 4 | 4 |
| melamine | | | | | | | |
| silicone anti- | 3 | 3 | 3 | 3 | 3 | 3 | 3 |
| foaming agent | | | | | | | |

B-1: 2-benzyl-2-dimethyl amine-1-(4-morpholino phenyl)-butanol-1
B-2: 2,4,6-trimethyl benzoyl-diphenyl-phosphine oxide
C-1: dipentaerythritol hexaacrylate
D: made by DuPont, brand name: DBE [dimethyl adipate: 10 to 25%, dimethyl glutarate: 55 to 65%, dimethyl succinate: 15 to 25%]
DPM: dipropylene glycol monomethyl ether oil-based aromatic solvent: made by Idemitsu Kosan, brand name: Ipzole 150
filler: barium sulfate (B-30 made by Sakai Chemical Industry)
E-1: cresol novolac type epoxy resin (made by Tohto Kasei Co., brand name YDCN-704P, epoxy equivalent weight 210)
E-2: phenol novolac type epoxy resin (made by Nippon Kayaku, RE 306, epoxy equivalent weight: 178)

Performance Evaluation:

(1) Dry-to-the-Touch Condition after Preliminary Drying

For each of the above working examples 1 to 5 and comparison examples 1 to 2, a substrate was made by taking a buff-roll-polished copper-covered laminated board, coating its entire surface, by screen printing, with the alkali developing type photosensitive resin composition, drying for 30 minutes at 80° C., then the dry-to-the-touch condition of its paint film surface was evaluated.

◯: no stickiness at all
Δ: slight stickiness
X: stickiness

### (2) Reagglomeration Test

For each of the above working examples 1 to 5 and comparison examples 1 to 2, 50 g of the alkali developing type photosensitive resin composition was weighed out and left standing for 1 day at 50° C., then was left standing for another 1 day at 4° C., then was checked for the presence of crystal material in the composition.

◯: no crystal material at all
Δ: some crystal material

### (3) Viscosity Evaluation

For each of the above working examples 1 to 5 and comparison examples 1 to 2, 50 g of the alkali developing type photosensitive resin composition was weighed out and left standing for 5 days at 50° C., then the viscosity was measured using an E-type viscometer, and the viscosity difference (rate of increase in viscosity) was evaluated as compared with before being left standing at 50° C.

◯: viscosity increase 25% or less
Δ: viscosity increase 26% or more but 40% or less
X: viscosity increase 41% or more

### (4) Appearance Evaluation

For each of the above working examples 1 to 5 and comparison examples 1 to 2, a substrate was made by coating a buff-roll-polished copper-covered laminated board (coating area: 105 cm²) over its entire surface, by screen printing, with the alkali developing type photosensitive resin composition, and was dried for 30 minutes at 80° C., then by visual inspection a check was made for the presence of any grains on the surface of the paint film. The film thickness after drying was 15 μm±2 μm.

◯: number of grains is zero
Δ: number of grains is 5 or fewer
X: number of grains is 6 or more

### (5) Solder Heat Resistance

For each of the above working examples 1 to 5 and comparison examples 1 to 2, a paint film made by photocuring and thermosetting the alkali developing type photosensitive resin composition was dipped twice for 10 seconds in a solder bath at 260° C. using a rosin system and water-soluble flux according to the testing method of JIS C6481, and the state of the paint film was evaluated. The evaluation standards are as follows.

◯: no peeling or other abnormality in the paint film
Δ: slight peeling in the paint film
X: blistering and peeling in the paint film

The results of the above tests are presented in Table 2.

TABLE 2
[Wex = Working example, Cex = Comparison example]

| | | | Wex | Wex | Wex | Cex 1 | Cex 2 |
|---|---|---|---|---|---|---|---|
| | Wex 1 | Wex 2 | 3 | 4 | 5 | 1 | 2 |
| contains | no | no | no | no | no | yes | no |
| naphthalene | | | | | | | |
| dry-to-touch | ◯ | ◯ | Δ | Δ | Δ | ◯ | Δ |
| after preliminary | | | | | | | |
| drying | | | | | | | |
| reagglomeration | ◯ | ◯ | ◯ | ◯ | ◯ | ◯ | X |
| test | | | | | | | |
| viscosity | ◯ | Δ | ◯ | Δ | Δ | X | X |
| appearance | ◯ | Δ | ◯ | Δ | ◯ | ◯ | X |
| solder heat | ◯ | ◯ | ◯ | ◯ | Δ | ◯ | ◯ |
| resistance | | | | | | | |

From the results shown in the above Table 2, it is clear that the alkali developing type photosensitive resin composition of working examples 1 to 5, in which a dibasic acid ester is used as the solvent, is better than the comparison examples in all the properties: dry-to-the-touch condition, reagglomeration tests, viscosity evaluation, and appearance evaluation. It is also clear that the results are particularly good for working example 1, working example 2, and working example 3, which each contain a dibasic acid ester in the solvent or dilute solvent used for the varnish.

On the other hand, it was learned that comparison example 1, which uses carbitol acetate as the solvent used for the varnish and uses a dipropylene glycol monoethyl ether as the oil-based aromatic solvent and dilute solvent, contains naphthalene in the oil-based aromatic solvent, causing concern for harm to the human body, and that its viscosity evaluation results are poor and its storage stability is inferior. Also, it was learned that comparison example 2, which uses carbitol acetate and dipropylene glycol monomethyl ether as the solvent used for the varnish and uses carbitol acetate as the dilute solvent, yields poor results in the viscosity evaluation and the reagglomeration test, has inferior storage stability, has many grains on its paint film surface, and yields poor appearance evaluation results.

1. An alkali developing type photosensitive resin composition, comprising:
a carboxyl group-containing resin;
a photopolymerization initiator;
a compound that comprises two or more ethylenic unsaturated groups; and
a dibasic acid ester.

2. An alkali developing type photosensitive resin composition of claim 1, wherein the dibasic acid ester is a mixture of 0 to 40 wt % dialkyl adipate, 40 to 80 wt % dialkyl glutarate, and 5 to 40 wt % dialkyl succinate, and alkyls of the dialkyl adipate, dialkyl glutarate, and the dialkyl succinate are each independently an alkyl group comprising from 1 to 6 carbon atoms or a cycloalkyl group comprising from 5 to 8 carbon atoms.

3. An alkali developing type photosensitive resin composition of claim 1, wherein the dibasic acid ester is a mixture of dimethyl adipate, dimethyl glutarate, and dimethyl succinate.

4. An alkali developing type photosensitive resin composition of claim 1, wherein a content of the dibasic acid ester is from 1 to 60 parts by weight per 100 parts by weight of the carboxyl group-containing resin.

5. An alkali developing type photosensitive resin composition of claim 1, further comprising:
a thermosetting component.

6. An alkali developing type photosensitive resin composition of claim 1, which is suitable as a coating onto a substrate.

7. A dry film obtained by a process comprising:
coating onto a carrier film the alkali developing type photosensitive resin composition of claim 1; and
drying the resin composition.

8. A cured product obtained by a process comprising:
taking the alkali developing type photosensitive resin composition of claim 1, or a dry film obtained by coating a carrier film with the alkali developing type photosensitive resin composition and drying a coated resin composition; and
performing photocuring, or photocuring and thermosetting, on a substrate.

9. A printed circuit board, comprising:
a cured product obtained by a process including
taking the alkali developing type photosensitive resin composition of claim 1, or a dry film obtained by coating a carrier film with the alkali developing type photosensitive resin composition and drying a coated resin composition, and
performing photocuring, or photocuring and thermosetting.

10. A dry film obtained by a process comprising:
coating onto a carrier film the alkali developing type photosensitive resin composition of claim 2; and
drying a coated resin composition.

11. A dry film obtained by a process comprising:
coating onto a carrier film the alkali developing type photosensitive resin composition of claim 3; and
drying a coated resin composition.

12. A dry film obtained by a process comprising:
coating onto a carrier film the alkali developing type photosensitive resin composition of claim 4; and
drying a coated resin composition.

13. A dry film obtained by a process comprising:
coating onto a carrier film the alkali developing type photosensitive resin composition of claim 5; and
drying a coated resin composition.

14. A cured product obtained by a process comprising:
taking the alkali developing type photosensitive resin composition of claim 2, or a dry film obtained by coating a carrier film with the alkali developing type photosensitive resin composition and drying a coated resin composition; and
performing photocuring, or photocuring and thermosetting, on a substrate.

15. A cured product obtained by a process comprising:
taking the alkali developing photosensitive resin composition of claim 3, or a dry film obtained by coating a carrier film with the alkali developing type photosensitive resin composition and drying a coated resin composition; and
performing photocuring, or photocuring and thermosetting, on a substrate.

16. A cured product obtained by a process comprising:
taking the alkali developing photosensitive resin composition of claim 4, or a dry film obtained by coating a carrier film with the alkali developing type photosensitive resin composition and drying a coated resin composition; and
performing photocuring, or photocuring and thermosetting, on a substrate.

17. A cured product obtained by a process comprising:
taking the alkali developing photosensitive resin composition of claim 5, or a dry film obtained by coating a carrier film with the alkali developing type photosensitive resin composition and drying a coated resin composition; and
performing photocuring, or photocuring and thermosetting, on a substrate.

18. A printed circuit board, comprising:
a cured product obtained by a process including
taking the alkali developing photosensitive resin composition of claim 2, or a dry film obtained by coating a carrier film with the alkali developing type photosensitive resin composition and drying a coated resin composition, and
performing photocuring, or photocuring and thermosetting.

19. A printed circuit board, comprising:
a cured product obtained by a process including
taking the alkali developing photosensitive resin composition of claim 3, or a dry film obtained by coating a carrier film with the alkali developing type photosensitive resin composition and drying a coated resin composition, and
performing photocuring, or photocuring and thermosetting.

20. A printed circuit board, comprising:
a cured product obtained by a process including
taking the alkali developing photosensitive resin composition of claim 4, or a dry film coating a carrier film with the alkali developing type photosensitive resin composition and drying a coated resin composition, and
performing photocuring, or photocuring and thermosetting.
